(19) United States
(12) Patent Application Publication
(10) Pub. No.: US 2015/0192625 A1
(43) Pub. Date: Jul. 9, 2015

(54) REMOTE METER READER

(71) Applicant: Kabushiki Kaisha Toshiba, Tokyo (JP)

(72) Inventor: Koichi Sato, Tachikawa (JP)

(21) Appl. No.: 14/475,121

(22) Filed: Sep. 2, 2014

(30) Foreign Application Priority Data
Jan. 6, 2014 (JP) 2014-000297

(51) Int. Cl. G01R 21/00

(52) U.S. Cl. CPC G01R 21/00

(57) ABSTRACT

According to one embodiment, a remote meter reader includes a power line configured to supply power, a meter reader unit and including a power measuring unit configured to measure an amount of the power, and a power amount display configured to display the amount of the power, a holder holding part of the power line, a communication board including at least one antenna, and a cable configured to electrically connect the meter reader unit to the communication board. The power amount display is provided on the surface portion of the meter reader unit which is positioned opposite to the position of the communication board. The communication board is provided separate from the surface of the holder.

### CROSS-REFERENCE TO RELATED APPLICATIONS

This application is based upon and claims the benefit of priority from Japanese Patent Application No. 2014-000297, filed Jan. 6, 2014, the entire contents of which are incorporated herein by reference.

### FIELD

Embodiments described herein relate generally to an antenna for smartmeters.

### BACKGROUND

Domestic power companies have recently made approaches to spread smartmeters as remote meter readers. A certain power company is planning to provide smartmeters to 27,000,000 family units within a decade. The smartmeter is a next-generation power meter with an energy management function, which enables interactive communication between a customer and a power company.

An antenna for smartmeters is generally internally mounted in view of strength, waterproof, etc. However, the smartmeters contain many metal members. If the antenna is arranged close to the metal members, its performance will be degraded.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is a perspective view of a remote meter reader 1 according to a first embodiment;

FIG. 2A is a schematic front view of the remote meter reader 1;

FIG. 2B is a sectional side view taken along line A-A of FIG. 2A;

FIG. 3A is a front view showing the internal structure of the remote meter reader 1;

FIG. 3B is a sectional side view taken along line A-A of FIG. 3A;

FIG. 4 is a block diagram showing a power measuring unit;

FIG. 5 is a block diagram showing a communication unit; and

FIG. 6 is a front view of a remote meter reader 1 according to a second embodiment.

### DETAILED DESCRIPTION

Various embodiments will be described hereinafter with reference to the accompanying drawings.

In general, according to one embodiment, a remote meter reader includes a power line configured to supply power, a meter reader unit connected to the power line and including a power measuring unit configured to measure an amount of the power, and a power amount display configured to display the amount of the power, a holder holding part of the power line, a communication board including at least one antenna, and a cable configured to electrically connect the meter reader unit to the communication board. The power amount display is provided on the surface portion of the meter reader unit which is positioned opposite to the position of the communication board with reference to the center of the surface. The communication board is provided separate from the surface of the holder and away from the power line.

Embodiments will be described with reference to the accompanying drawings.

### First Embodiment

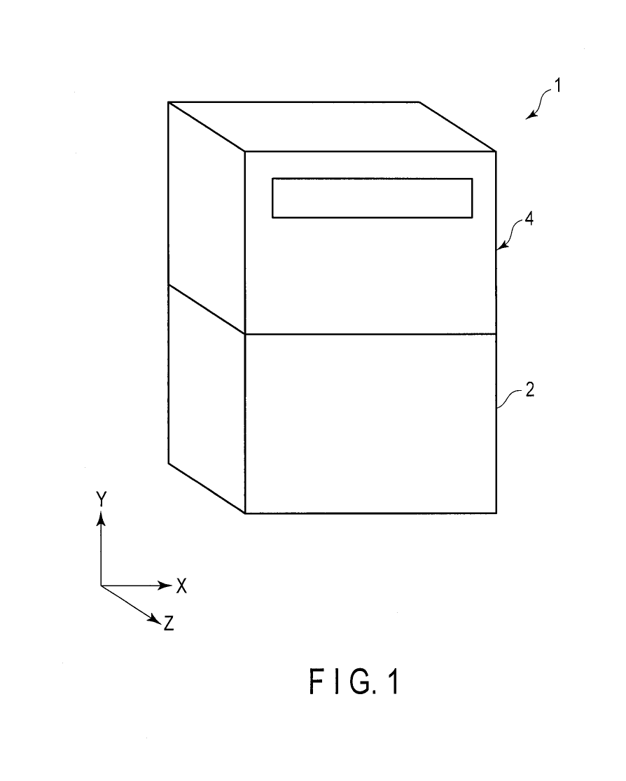

FIG. 1 is a perspective view of a remote meter reader 1. In the description below, the horizontal axis of the remote meter 1 in the FIG. 1 is defined as the X axis, the vertical axis of the remote meter 1 in the FIG. 1 is defined as the Y axis, and the axis perpendicular to the X- and Y-axes is defined as the Z axis. Further, the X-dimension is defined as the width, the Y-dimension is defined as the height, and the Z-dimension is defined as the thickness.

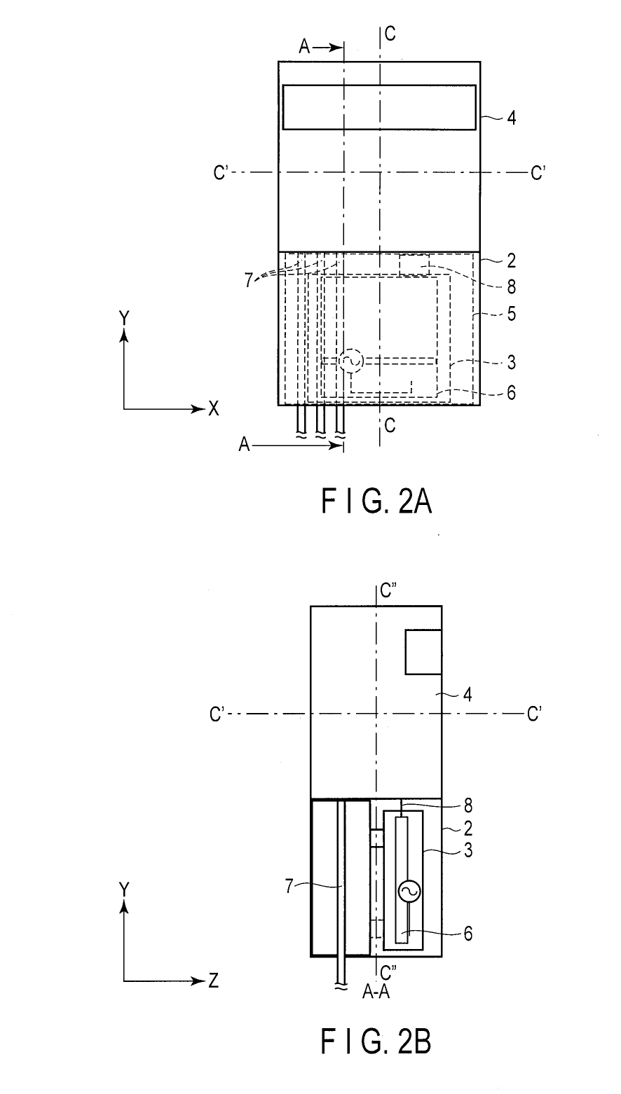

FIGS. 2A and 2B schematically show the remote meter reader 1. FIG. 2A is a schematic front view of the remote meter reader 1. In FIG. 2A, line C-C is the center line of the width of a power measuring unit 4 described later. FIG. 2B is a sectional side view taken along line A-A in FIG. 2A. In FIGS. 2A and 2B, line C′-C′ is the center line of the height of the power measuring unit 4. In FIG. 2B, line C″-C″ is the center line of the thickness of the power measuring unit 4. Further, in FIGS. 2A and 2B, detailed portions are not shown for facilitating the understanding of the structure.

As shown in FIGS. 1, 2A and 2B, the remote meter reader 1 incorporates an outer case 2, an inner case 3, a power measuring unit (meter reader unit) 4, a holder 5, a communication unit 6, power lines 7 and an interface cable 8. The remote meter reader 1 is an electric meter having a communication function, such as a smart meter. The remote meter reader 1 is installed in a customer's house to supply power from a power company to the distribution panel of the customer. Further, the remote meter reader 1 can automatically send data on the consumed power of the customer to, for example, the power company via the communication function. Furthermore, the use of the communication function enables remote control from a management center. For instance, electric connections and disconnections can be controlled remotely.

In FIG. 2A, the outer and inner cases 2 and 3 and the holder 5 are arranged so that their widthwise centers are aligned with the center line (line C-C) of the power measuring unit 4. However, the widthwise centers of the outer and inner cases 2 and 3 and the holder 5 may not be aligned with the center line. The widthwise center of the communication unit 6 may be or may not be aligned with the line C-C.

For instance, the outer case 2 is formed to the same width and thickness as those of the power measuring unit 4 described later, and to the same height as that of the holder 5 described later. The outer case 2 is formed of a non-metal material, e.g., a resin. The outer case 2 is arranged to cover the holder 5 and the communication unit 6 held by the inner case 3 described later.

The inner case 3 is formed to a size that permits itself to contain the communication unit 6 and to be contained in the outer case 2. The inner case 3 is formed of a nonmetal material. For instance, the inner case 3 is formed of a resin. The inner case 3 serves as a protection member for protecting the communication unit 6, and as a spacer for holding the communication unit 6 at a predetermined distance from the holder 5. For example, the inner case 3 incorporates a housing portion covering the communication unit 6, and legs fixed to the holder 5, as is shown in FIG. 2B. The legs of the inner case 3 extend, for example, along the Z axis. Further, the housing portion of the inner case 3 has a hole for inserting an interface cable 8 described later, as shown in FIG. 2B. The inner case 3 is covered with the outer case 2, and is extended along the Z axis. The legs of the inner case 3 are secured to the surface of the holder 5. The legs of the inner case 3 are not indispensable to the case 3. It is sufficient if the inner case 3 can serve as a spacer for maintaining the distance between the holder 5 and the communication unit 6.

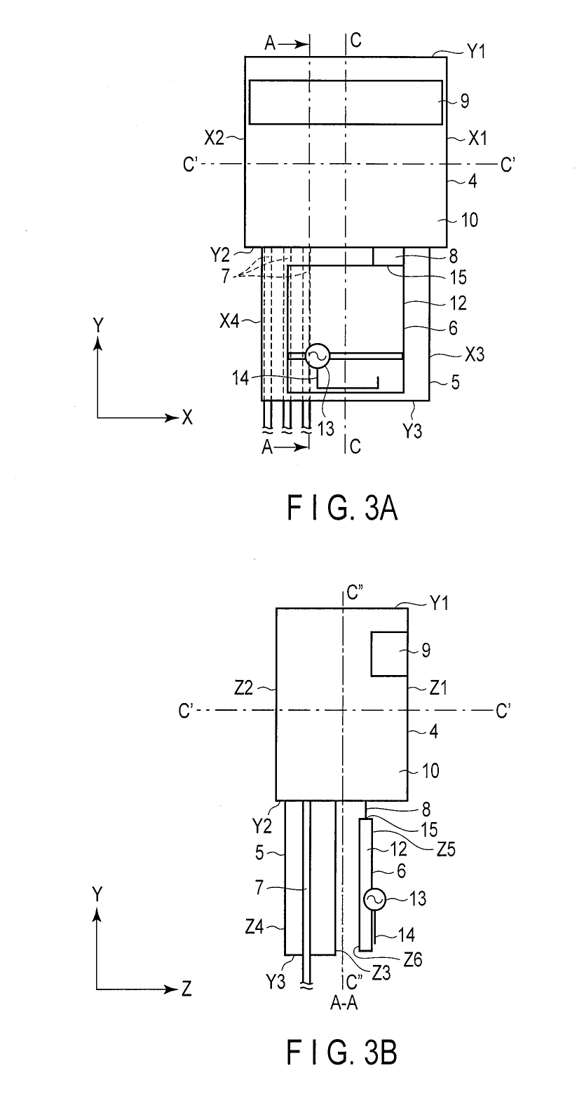

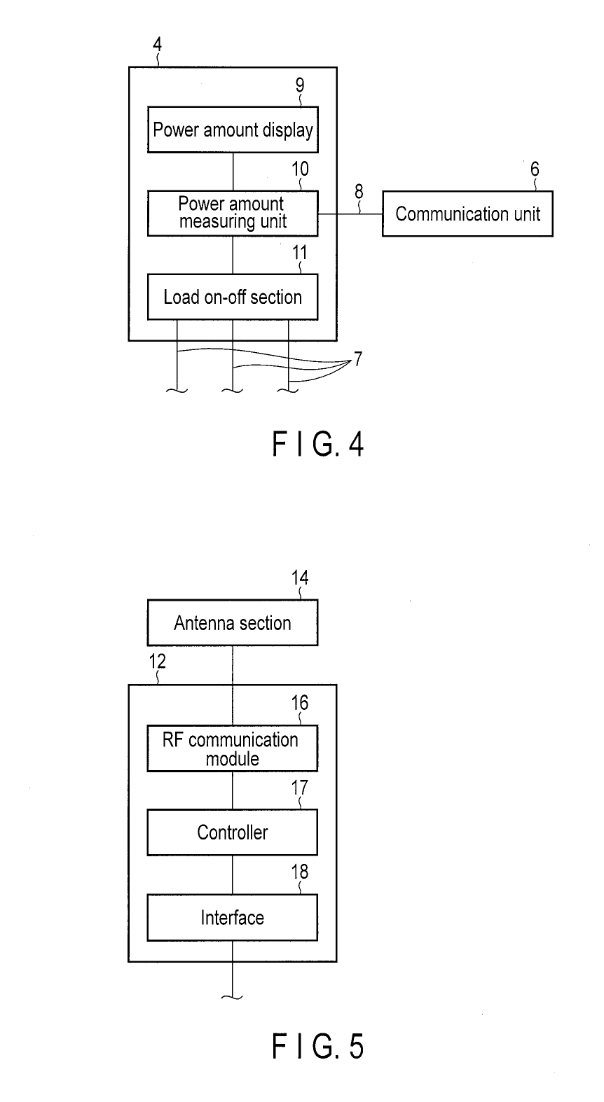

FIGS. 3A and 3B schematically show the internal structure of the remote meter reader 1. FIG. 3A is a front view showing the internal structure of the remote meter reader 1. FIG. 3B is a sectional side view taken along line A-A. In FIGS. 3A and 3B, the outer and inner cases 2 and 3 are removed to facilitate the understanding of the internal structure. FIG. 4 is a block diagram of the power measuring unit 4. The internal structure of the remote meter reader 1 will be hereinafter described in detail with reference to FIGS. 3A and 3B and FIG. 4.

As shown in FIG. 4, the power measuring unit 4 incorporates a power amount display 9, a power measuring section 10, and a load on-off section 11. The power measuring unit 4 can measure the amount of power consumed by a customer, record the measurement data, and send necessary data to the communication unit 6. The power measuring unit 4 can also receive an external control signal from, for example, the management center, and send a signal for controlling the supply of power to each portion of a customer's house. Each portion of the customer's house means, for example, a distribution panel, various electrical devices, such as lighting equipment and TV, etc. Thus, the power measuring unit 4 controls opening/closing of the circuit of each portion of the customer's house in accordance with instructions from, for example, a power company, thereby supplying power to the customer and interrupting the supply of power. As shown in FIGS. 3A and 3B, the housing of the power measuring unit 4 has two surfaces (X1, X2) extending along the plane perpendicular to the X axis, two surfaces (Y1, Y2) extending along the plane perpendicular to the Y axis, and two surfaces (Z1, Z2) extending along the plane perpendicular to the Z axis. The two surfaces extending along the plane perpendicular to the X axis will hereinafter be referred to as “surfaces X1 and X2.” Similarly, the two surfaces extending along the plane perpendicular to the Y axis will be referred to as “surfaces Y1 and Y2,” and two surfaces extending along the plane perpendicular to the Z axis will be referred to as “surfaces Z1 and Z2.” The surfaces extending along the X-, Y- and Z-axes may not be flat. Further, the X1 side along the X axis will be referred to as the right side, and the X2 side will be referred to as the left side. Similarly, the Y1 side along the Y axis will be referred to as the upper side, and the Y2 side will be referred to as the lower side. The Z1 side along the Z axis will be referred to as the front side, and the Z2 side will be referred to as the rear side. The power measuring unit 4 may be formed cylindrically, with the power amount display 9 provided at the bottom (the front or rear side).

The power amount display 9 visually displays the amount of power measured by the power measuring section 10. The power amount display 9 is formed of a metal material and has a shape with long and short sides. The power amount display 9 is formed like, for example, a rectangular parallelepiped elongated along the X axis, and has a size that permits itself to be contained in the power measuring unit 4. To visually display the amount of power measured by the power measuring section 10, the power amount display 9 has a power-amount display section exposed in the front surface thereof. Namely, the power-amount display section of the power amount display 9 is arranged externally visibly in the surface of the power measuring unit 4. For instance, the power-amount display section is arranged so that it can be seen from a window formed in the surface of the power measuring unit 4. Accordingly, along the Z axis, the power amount display 9 is provided in contact with one of the two surfaces Z1 and Z2. As is shown in FIGS. 3A and 3B, the power amount display 9 is provided in front of the center line C″-C″ of the thickness of the power measuring unit 4 and in contact with the surface Z1 of the power measuring unit 4. Further, along the Y axis, the power amount display 9 is provided close to one of the two surfaces Y1 and Y2. In FIGS. 3A and 3B, the power amount display 9 has its long sides positioned above and in parallel with the center line C′-C′ of the height of the power measuring unit 4. The shape of the power amount display 9 is not limited to the rectangular parallelepiped.

The power measuring section 10 is contained in the power measuring unit 4, and is configured to measure the amount of power consumed by the customer. As shown in FIG. 4, the power measuring section 10 is electrically connected to the power amount display 9 and the communication unit 6 to supply them with a signal indicating the measured power amount. The power measuring section 10 includes, for example, a metal member as a structural member.

The load on-off section 11 is a switch for opening and closing the cable run of power, and is electrically connected to the power measuring section 10. In accordance with a control signal received by the communication unit 6 described later, the load on-off section 11 controls the supply of power and the interruption of the power supply. As shown in FIG. 4, the load on-off section 11 is connected to power lines 7, described later, within the power measuring unit 4.

The holder 5 is formed of, for example, a metal material, and formed thinner than the power measuring unit 4. The holder 5 holds part of the power lines 7 described later. As shown in FIG. 3A, the holder 5 holds the power lines 7 on the left side of the line C-C. Further, as shown in FIGS. 3A and 3B, the housing of the holder 5 has two surfaces (X3 and X4) extending along the plane perpendicular to the X axis, one surface(Y3) extending along the plane perpendicular to the Y axis, and two surfaces (Z3 and Z4) extending along the surface perpendicular to the Z axis. In the same way as in each surface of the power measuring unit 4, the two surfaces extending along the plane perpendicular to the X axis will hereinafter be referred to as surfaces X3 and X4, and the surfaces along the Y- and Z-axes be referred to as surfaces Y3, Y4, Z3 and Z4. The surfaces extending along the X-, Y- and Z-axes may not be flat. It should be noted that the surface perpendicular to the Y axis and opposite to the surface Y3 do not indicate in FIGS. 3A and 3B since they are connected to the power measuring unit 4 as described later. Further, as in the power measuring unit 4, the X3 side and the X4 side along the X axis will be referred to as the right side and the left side, respectively. The Y3 side and the Y4 side along the Y axis will be referred to as the upper side and the lower side, respectively. The Z3 side and the Z4 side along the Z axis will be referred to as the front side and the rear side, respectively.

The holder 5 is connected to one of the two surfaces of the power measuring unit 4. For instance, as shown in FIGS. 3A and 3B, the holder 5 is provided on the Y side of the power measuring unit 4. Further, along the Z axis, the holder 5 is provided on the rear or front side of the power measuring unit 4 with respect to the center of the thickness thereof. In FIG. 3B, the holder 5 is arranged on the rear side of the line C″-C″.

The communication unit 6 includes a communication circuit board 12, a feeding point 13, an antenna section 14, and a connector 15. The communication unit 6 uses a part of the communication circuit board 12 as a ground, and uses another part of the communication circuit board 12 as part of an antenna. The communication unit 6 can request the power measuring unit 4 to supply, for example, the data requested by a communication management center, thereby obtaining the data. As shown in FIG. 3B, the communication unit 6 has two surfaces (Z5 and Z6) extending along the plane perpendicular to the Z axis of the communication circuit board 12. In the description below, the two surfaces along the Z axis will be referred to as surfaces Z5 and Z6. Further, along the Z axis, the Z1 side will be referred to as the front side, and the Z2 side be referred to as the rear side. The surfaces extending along the Z axis may not be flat. Since the communication unit 6 is formed flat, no description will be given of the surfaces extending along the planes perpendicular to the X- and Y-axes.

Along the Y axis, the communication unit 6 is provided away from the power amount display 9 that is mounted in the power measuring unit 4. In FIG. 3A, since the power amount display 9 is provided on the Y1 side with respect to the line C′-C′, the communication unit 6 is provided below the surface Y2 with a predetermined distance therefrom. The predetermined distance along the Y axis between the communication unit 6 and the power measuring unit 4 is set such that, for example, the communication unit 6 is away from the power amount display 9 as far as possible within the outer case 2.

Along the Z axis, the communication unit 6 is provided at a predetermined distance from the surface Z3 of the holder 5. For instance, as shown in FIG. 3B, the surface Z6 of the communication unit 6 opposes the surface Z3 of the holder 5. As mentioned above, the communication unit 6 is held by the inner case 3 at a predetermined distance from the surface Z3, although this is not shown in FIG. 3B. In this state, the legs of the inner case 3 are secured to the surface Z3 as shown in FIG. 2B. The predetermined distance along the Z axis between the communication unit 6 and the holder 5 is set such that, for example, the communication unit 6 is away from the holder 5 as far as possible within the outer case 2.

FIG. 5 is a block diagram showing the communication unit 6. The communication circuit board 12 of the communication unit 6 includes an RF communication module 16, a controller 17 and an interface 18. The RF communication module 16 is a communication circuit having a wireless module or a wireless circuit chip. The RF communication module 16 is connected to the antenna section 14 via the feeding point 13. The controller 17 controls the circuit of the RF communication module. The controller 17 is formed of, for example, a microcomputer for controlling a communication circuit. The interface 18 electrically connects the controller 17 to the interface cable 8 that is connected to the connector 15.

The feeding point 13 is provided on the communication circuit board 12 at distances from the metal members and the power lines 7. Namely, the feeding point 13 is provided at predetermined distances from the power measuring unit 4 and the holder 5 as shown in FIGS. 3A and 3B. The communication circuit board 12 receives power of a frequency for use from the communication unit 6. For instance, the feeding point 13 is provided on the lower left portion of the surface Z5 of the communication circuit board 12 with respect to the front-side line C-C, as is shown in FIG. 3A.

In the communication unit 6, the antenna section 14 is provided on the surface Z5 of the communication circuit board 12. In the embodiment, it is assumed that the antenna section 14 is mounted as a printed pattern on the communication circuit board 12. The connector 15 is provided on the communication circuit board 12, and is electrically connected to, for example, a microcomputer incorporated in the communication circuit board 12.

The antenna section 14 is provided at predetermined distances from the metal members, the power lines 7, the interface cable 8 and the connector 15. For instance, as shown in FIG. 3A, the antenna section 14 is provided at a distance along the Z axis from the holder 5 that includes a metal member and the power lines 7. Further, in the communication unit 6, the antenna section 14 is provided close to the side opposite to the power measuring unit 4 side. In addition, the antenna section 14 is provided at a predetermined distance from the connector 15, and has one end connected to the feeding point 13 and the other end kept open.

The open end of the antenna section 14 is positioned at predetermined distances from the metal members, the power lines 7, the interface cable 8 and the connector 15. In addition, since in general, voltage is increased within power lines, the open end of the antenna section 14 is provided away from, for example, the power lines 7. For instance, the open end of the antenna section 14 is provided within the communication circuit board 12. In FIG. 3B, the open end of the antenna section 14 linearly downwardly extends along the Y axis from the feeding point 13 to a lower side of the communication circuit board 12, then extends along this lower side, i.e., along the X axis away from the holder 5 which holds part of the lines 7, and linearly upwardly extends along the Y axis. At this time, the connector 15 is provided at a distance from the antenna section 14. For instance, in FIG. 3A, the connector 15 is provided on the upper left portion of the communication circuit board 12 with respect to the line C-C. It is sufficient if the open end of the antenna section 14 is provided away from the members, such as the metal members and the power lines, which will adversely affect the antenna performance.

The antenna section 14 is, for example, a monopole antenna, a dipole antenna, etc. If the antenna section 14 is a monopole antenna, the length of the antenna section 14 is set to, for example, ¼ of the wavelength corresponding to the frequency used.

The power lines 7 are connected to the load on-off section 11 contained in the power measuring unit 4, as is shown in FIG. 4. As shown, the power lines 7 extend from the load on-off section 11 of the power measuring unit 4 to the outside of the power measuring unit 4. The externally extended power lines 7 downwardly extend along the Y axis as shown in FIG. 3A. Further, as shown in FIG. 3A, the portions of the power lines 7, which extend from the bottom of the power measuring unit 4 and have a predetermined length, are held by the holder 5. In addition, along the X axis, the power lines 7 are arranged on the left side of the line C-C in FIG. 3A. The power lines 7 are used to supply power from a power company to the distribution panel of a customer via the load on-off section 11.

The interface cable 8 is used to send signals between the power measuring unit 4 and the communication unit 6. The interface cable 8 is also used to supply power to the communication unit 6. The interface cable 8 has one end connected to the interior of the power measuring unit 4, and the other end connected to the connector 15. As shown in FIGS. 3A and 3B, the interface cable 8 outwardly extends from the surface Y2 of the power measuring unit 4. For example, the interface cable 8 outwardly extends on the right side of the line C-C of the power measuring unit 4, and from the front side of the line C″-C″ of the power measuring unit 4, as is shown in FIGS. 3A and 3B. In this case, one end of the interface cable 8, which outwardly extends, is connected to the connector 15.

By virtue of this structure, the power supplied from the power company is fed to, for example, each electric appliance of the customer via the power measuring unit 4 and the power lines 7 of the remote meter reader 1. Further, power is also supplied from the power measuring section 10 to the communication unit 6 via the interface cable 8. The amount of power measured by the power measuring section 10 is sent in the form of a signal to the power amount display 9. The signal indicating the power amount is also sent to the communication unit 6 via the interface cable 8. The communication unit 6, in turn, supplies the feeding point 13 with a high-frequency signal corresponding to the used power. The communication unit 6 supplies the management center with an electric wave with information associated with the used power via the antenna section 14. Further, the communication unit 6 receives, from, for example, the management center via the antenna section 14, an electric wave with an instruction, such as a control instruction. Yet further, the communication unit 6 adjusts the amount of power to be supplied to, for example, each electric appliance of the customer by exchanging signals with it, and obtains information on the power consumption thereof. The thus obtained information is received by the antenna section 14 and sent to the power measuring section 10 via the communication circuit board 12. At this time, the power measuring section 10 can control the amount of power. Further, the obtained information can be sent to the management center or the terminal of the customer. Such transmission and reception of signals via the antenna section 14 between the communication unit 6 and each communication place are performed arbitrarily.

In the embodiment, the antenna section 14 used for signal transmission and reception for arbitrary communication is provided away along the Y axis from the structural elements including the metal members. This suppresses adverse influence on the signals transmitted from and received by the antenna section 14, i.e., suppresses degradation of the performance of the antenna section 14.

The open end of the antenna section 14 is provided at a distance along the Y axis from the power measuring unit 4 including the metal members, and at distances from the power lines along the Z axis. As a result, degradation of the performance of the antenna section 14 is suppressed.

Further, in the embodiment, the antenna section 14 is a pattern printed on the communication unit 6. However, a communication antenna having a communication function can be provided as a member separate from the communication unit.

### Second Embodiment

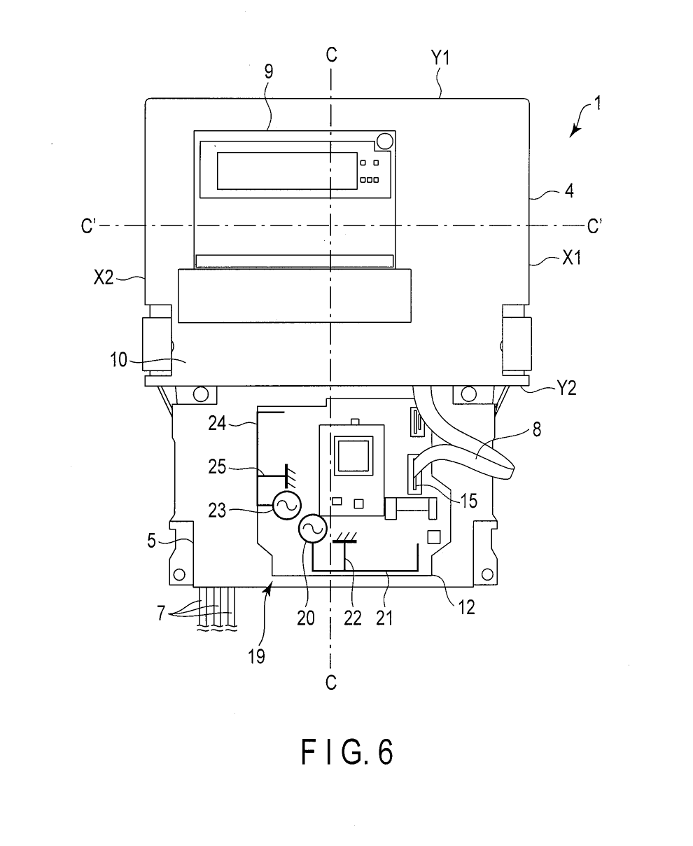

Referring then to FIG. 6, a second embodiment will be described. A remote meter reader 1 according to the second embodiment has substantially the same structure as the remote meter reader 1 of the first embodiment. Therefore, in the second embodiment, elements similar to those of the first embodiment are denoted by corresponding reference numbers, and no detailed description will be given thereof. In the second embodiment, a communication unit 19 described later corresponds to a diversity device.

FIG. 6 is a front view of the remote meter reader 1 of the second embodiment. FIG. 6 is a view similar to but more detail than FIG. 3A. The communication unit 19 shown in FIG. 6 differs in structure from the communication unit 6 shown in FIGS. 3A and 3B.

The communication unit 19 of the second embodiment incorporates a communication circuit board 12, a connector 15, a first feeding point 20, a first antenna section 21, a second feeding point 23 and a second antenna section 24. The communication unit 19 is provided at distances from the holder 5 and the power lines 7 along the Z axis as in the first embodiment. For instance, the communication unit 19 is held by the inner case 3 in front of the surface Z3 of the holder 5 at a predetermined distance therefrom, as in the first embodiment. In a communication antenna unit 15, the first and second antenna sections 21 and 24 are arranged orthogonal to each other, as will be described in detail later. In this case, a wireless circuit on the communication circuit board 12, for example, is provided on the plane formed by the lines along the first and second antenna sections 21 and 24 on the communication circuit board 12. Further, on the communication circuit board 12, the wireless circuit is provided in a position different from the first and second antenna sections 21 and 24.

In the communication unit 19, the first and second feeding points 20 and 23 are provided on the communication circuit board 12. Further, the first and second feeding points 20 and 23 are provided at certain distances from the first interface cable 8 and the connector 15. For instance, as shown in FIG. 6, the first feeding point 20 is provided close to the left side of the communication circuit board 12, and the second feeding point 23 is provided close to the lower side of the communication circuit board 12. Further, the first feeding point 20 is provided in a lower right position relative to the second feeding point 23.

In the communication unit 19, the first antenna section 21 has a first short-circuiting portion 22, and is located at predetermined distances from the metal members, the power lines 7, the interface cable 8 and the connector 15. For instance, the first antenna section 21 is located at a predetermined distance along the Z axis from the holder 5 including a metal member and the power lines 7, as shown in FIG. 6. Further, in the communication unit 19, the first antenna section 21 is provided close to the side away from the power measuring unit 4, and is also provided at a predetermined distance from the connector 15.

The first antenna section 21 has an end connected to the first feeding point 20, and the other end kept open. The open end of the first antenna section 21 is arranged at predetermined distances from the metal members, the power lines 7, the interface cable 8 and the connector 15. For instance, the first antenna section 21 linearly downwardly extends along the Y axis from the first feeding point 20 to a lower side of the communication circuit board 12, then extends along this lower side, i.e., along the X axis away from the holder 5, and linearly upwardly extends along the Y axis. It is sufficient if the open end of the first antenna section 21 is provided away from the power lines 7 that are not held by the power measuring unit 4 and the holder 5.

The first short-circuiting portion 22 branches from the first antenna section 21, and has one end connected as a ground to the communication circuit board 12. For example, the first short-circuiting portion 22 branches from the part of the first antenna section 21 extending along the above-mentioned lower side of the combination circuit board 12, i.e., along the X axis.

In the communication unit 19, the second antenna section 24 has a second short-circuiting portion 25. The second antenna section 24 is arranged orthogonal to the first antenna section 21, and is also located at predetermined distances from the metal members, the power lines 7, the interface cable 8 and the connector 15. For instance, the second antenna section 24 is located at a predetermined distance along the Z axis from the holder 5 including a metal member and the power lines 7, as shown in FIG. 6. Further, the second antenna section 24 is provided at a predetermined distance from the connector 15. For instance, in FIG. 6, the second antenna section 24 is provided close to the side of the communication circuit board 12 that is away from the connector 15.

The second antenna section 24 has one end connected to the second feeding point 23, and the other end kept open. For instance, in FIG. 6, the second antenna section 24 linearly leftward extends from the second feeding point 23 along the X axis, then linearly upwardly extends to the upper side of the communication circuit board 12 along the left side thereof, i.e., along the Y axis, and then linearly rightward extends along the X axis.

The second short-circuiting portion 25 branches from the second antenna section 24, and has one end connected as a ground to the communication circuit board 12. For example, the second short-circuiting portion 25 branches from the part of the second antenna section 24 extending along the above-mentioned left side of the combination circuit board 12, i.e., along the Y axis.

Each of the first and second short-circuiting portions 22 and 25 enhances its impedance and suppresses the current flowing through the other antenna.

In the communication unit 19, the connector 15 is provided on the surface Z5 of the communication circuit board 12, and is provided at distances from the first and second antenna sections 21 and 24. For instance, as shown in FIG. 6, the connector 15 is provided close to the right side of the surface Z5 of the communication circuit board 12. Namely, the connector 15 is provided close to the right side of the communication unit 6.

By virtue of the above structure, the communication unit 19 transmits orthogonalized polarized waves through the first and second antenna sections 21 and 24. The communication unit 19 transmits radio waves carrying information associated with used power to the management center via the first and second antenna sections 21 and 24. Further, the communication unit 19 receives radio waves carrying, for example, control commands from, for example, the management center via the first and second antenna sections 21 and 24. Yet further, the communication unit 19 acquires information associated with, for example, adjustment of the amount of power supplied to each electric appliance of the customer, and the amount of power consumed by each electric appliance, by signal transmission and reception to and from each electric appliance via the first and second antenna sections 21 and 24.

In the embodiments described above, in the communication unit 6, the first and second antenna sections 21 and 24 are arranged orthogonal to each other. By virtue of this arrangement, the polarized waves sent through the first and second antenna sections 21 and 24 are orthogonalized. The plurality of antenna sections also provide an effect of diversity. Yet further, the first and second short-circuiting portions 22 and 25 of the first and second antenna sections 21 and 24 enhance the impedances of the antennas, with the result that each of these antenna sections can suppress the current flowing through the other antenna. By the provision of the two short-circuiting portions and the orthogonal arrangement of the two antennas, the antennas can be isolated from each other to thereby suppress degradation of efficiency due to coupling.

In the above-described embodiments, since the communication unit is housed in the inner case, it is protected from external dust and shock. The legs of the inner case hold the communication unit, with the communication unit kept at predetermined distances along the Z axis from the holder including a metal member and the power lines. Further, since the open end of each antenna section is positioned away from the members, such as the metal members and the power lines, which will adversely affect the antenna performance, degradation of the antenna performance can be suppressed. Since the inner case is formed of a nonmetal material, such as a resin, it does not adversely affect the antenna performance, thereby suppressing degradation of the performance of the antenna sections due to the influence of, for example, power in the metal members and the power lines. Yet further, since the antenna sections are separate from the interface cable and the connector, antenna performance degradation due to the cable and connector can be suppressed.

Although some embodiments have been described above, they are merely examples and do not limit the scope of the invention. Various omissions, various replacements and/or various changes may be made in the embodiments without departing from the scope of the invention. The embodiments and their modifications are included in the scope of the invention, namely, in the inventions recited in the claims and equivalents thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A remote meter reader comprising:
a power line configured to supply power;
a meter reader unit connected to the power line and including a power measuring unit configured to measure an amount of the power, and a power amount display configured to display the amount of the power;
a holder holding part of the power line extending from the meter reader unit to an outside;
a communication board including at least one antenna and having a function of transmitting by radio measurement data of the meter reader unit via the at least one antenna; and
a cable configured to electrically connect the meter reader unit to the communication board,
wherein
the power amount display is provided on a surface portion of the meter reader unit which is positioned opposite to a position of the communication board with reference to a center of the surface; and
the communication board is provided separate from a surface of the holder and away from the power line.

2. The remote meter reader of claim 1, wherein the antenna includes a connection end connected to a feeding point on the communication board, a conductive portion extending from the connection end away from the meter reader unit, and an open end provided away from the connection end, the open end being a tip end of the conductive portion.

3. The remote meter reader of claim 2, wherein
the antenna is provided on a board surface of the communication board parallel and close to a surface of the meter reader unit provided with the power amount display; and
the antenna extends on the board surface along a side of the board surface close to the meter reader unit, extends away from the power line, and has part of the first open end bent within the board surface.

4. The remote meter reader of claim 3, wherein the antenna extends away from the power line.

5. The remote meter reader of claim 4, wherein the antenna is not parallel to the power line.

6. The remote meter reader of claim 2, further comprising a resin case which encloses the communication board to protect the same, and keeps a space between the communication board and the holder.

7. The remote meter reader of claim 6, further comprising a protective member of a size which enables the protective member to protect at least a range from a side of the meter reader unit close to the communication board, to the holder and the communication board.

8. The remote meter reader of claim 1, wherein
the communication board comprises a first antenna section, a second antenna section, a first feeding point, a second feeding point, and a connection point connected to the cable which extends from the meter reader unit;
the connection point is provided on a board surface of the communication board at a corner of the communication board close to the meter reader unit;
the first and second feeding points are provided on the communication board at corners opposite to the corner at which the connection point is provided;
the first antenna section has a first connection end connected to the first feeding point on the communication board, and a first open end opposite to the first connection end, the first antenna section extending on the board surface along a side of the board surface close to the meter reader unit, extending away from the power line, and having part of the first open end bent within the board surface; and
the second antenna section has a second connection end connected to the second feeding point on the communication board, and a second open end opposite to the second connection end, the second antenna section extending on the board surface along a side of the board surface perpendicular to the side along which the first antenna section extends, the second antenna section not crossing the first antenna section, part of the second open end being bent within the board surface.

9. The remote meter reader of claim 8, wherein the first and second antenna sections have respective short-circuiting portions connected to the communication board.

10. The remote meter reader of claim 9, wherein
the first feeding point is provided on the communication board closer than the second feeding point to a first side of the communication board opposite to a side of the communication board close to the meter reader unit; and
the second feeding point is provided closer than the first feeding point to a second side of the communication board, the second side being perpendicular to the first side.

11. The remote meter reader of claim 9, further comprising a resin case which encloses the communication board to protect the same, and keeps a space between the communication board and the holder.

12. The remote meter reader of claim 11, further comprising a protective member of a size which enables the protective member to protect at least a range from a side of the meter reader unit close to the communication board, to the holder and the communication board.
